(19) United States
(12) Patent Application Publication
(10) Pub. No.: US 2022/0077329 A1
(43) Pub. Date: Mar. 10, 2022

(54) SOLAR CELL WITH MXENE ELECTRODE

(71) Applicant: KING ABDULLAH UNIVERSITY OF SCIENCE AND TECHNOLOGY, Thuwal (SA)

(72) Inventors: Jr-Hau HE, Thuwal (SA); Hui-Chun FU, Thuwal (SA); Vinoth RAMALINGAM, Thuwal (SA); Chun-Ho LIN, Thuwal (SA)

(21) Appl. No.: 17/423,490

(22) PCT Filed: Feb. 18, 2020
(86) PCT No.: PCT/IB2020/051343

§ 371 Date: Jul. 16, 2021

Related U.S. Application Data
(60) Provisional application No. 62/807,466, filed on Feb. 19, 2019.

(51) Int. Cl. H01L 31/0224; H01L 31/074; H01L 31/0216; H01L 31/18

(52) U.S. Cl. CPC H01L 31/022425; H01L 31/074; H01L 31/1868; H01L 31/1804; H01L 31/02168

(57) ABSTRACT

A solar cell includes a p-type silicon layer having a first side and a second side and an n-type silicon layer having a first side and a second side. The first side of the n-type silicon layer is arranged on the second side of the p-type silicon layer. The solar cell also includes a first metal electrode arranged on the first side of the p-type silicon layer and a second metal electrode arranged on the second side of the n-type silicon layer. The second metal electrode includes an MXene.

### CROSS-REFERENCE TO RELATED APPLICATIONS

This application claims priority to U.S. Provisional Patent Application No. 62/807,466, filed on Feb. 19, 2019, entitled “MXENE ELECTRICAL CONTACTS FOR SOLAR CELLS,” the disclosure of which is incorporated herein by reference in its entirety.

### BACKGROUND

### Technical Field

Embodiments of the disclosed subject matter generally relate to a solar cell having an electrode comprising an MXene.

### Discussion of the Background

Energy sources that do not involve fossil fuels are currently an area of a great amount of research. Solar cells, which convert light into electricity, are one non-fossil fuel source that is of great interest. One of the biggest issues preventing wide-spread adoption of solar cells as an energy source is the efficiency of solar cells, i.e., how much of the absorbed light is converted into electricity, which is commonly expressed as power conversion efficiency (PCE).

Recently, graphene, a type of two-dimensional nanomaterial, was employed to improve the performance of solar cells. Two-dimensional nanomaterials are particularly attractive for solar cell applications due to their ease of fabrication, excellent optical properties, solution processable approach, low temperature fabrication, and tunable band structure at nanoscale dimensions. One such device was fabricated by transferring graphene onto an n-type silicon wafer to form an n-type silicon Schottky junction-based solar cell. The Schottky junction formed at the graphene/n-Si interface enhanced the power conversion efficiency (PCE) up to 1.5%. Graphene has also been used as a transparent electrode on a silicon heterojunction solar cell, which achieved a maximum power conversion efficiency of 4.98%. In order to further improve the performance of graphene based solar cells, a series of chemical modifications, which included chemical doping, molecular doping, ion doping, nanoparticle decoration, covalent and non-covalent functionalization on graphene, have been demonstrated. In addition to graphene, transition metal dichalcogenides (TMDs) are another two-dimensional material used to improve solar cells, with a monolayer MoS2/p-Si heterojunction fabricated by chemical vapor deposition (CVD), which achieved a maximum power conversion efficiency of 5.23%

Accordingly, existing solar cell technology is able to convert at best a little over one-twentieth of the absorbed light energy. Thus, there is a need for solar cells that are more efficient than existing solar cells.

### SUMMARY

According to an embodiment, there is a solar cell, which includes a p-type silicon layer having a first side and a second side and an n-type silicon layer having a first side and a second side. The first side of the n-type silicon layer is arranged on the second side of the p-type silicon layer. The solar cell also includes a first metal electrode arranged on the first side of the p-type silicon layer and a second metal electrode arranged on the second side of the n-type silicon layer. The second metal electrode includes an MXene.

According to another embodiment, there is a method for forming a solar cell. A silicon substrate is provided and a p-type layer is formed on a bottom of the silicon substrate. An n-type layer is formed on a top of the silicon substrate. A first metal electrode is formed on a bottom of the p-type layer and a second metal electrode is formed on a top of the n-type layer. The second metal electrode comprises an MXene.

According to a further embodiment, there is a solar cell array comprising a plurality of solar cells. Each of the plurality of solar cells comprises a p-type silicon layer having a first side and a second side and an n-type silicon layer having a first side and a second side. The first side of the n-type silicon layer is arranged on the second side of the p-type silicon layer. Each of the plurality of solar cells also comprises a first metal electrode arranged on the first side of the p-type silicon layer and a second metal electrode arranged on the second side of the n-type silicon layer. The second metal electrode includes an MXene.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic diagram of a solar cell according to embodiments;

FIG. 2 is a flow diagram of a method for forming a solar cell according to embodiments;

FIG. 3 is a schematic diagram of a solar cell according to embodiments;

FIG. 4 is a band diagram of a solar cell according to embodiments;

FIG. 5 is a graph of the absorbance, reflection, and transmission spectra of a solar cell according to embodiments;

FIG. 6 is a graph of the external quantum efficiency (EQE) spectra of a solar cell according to embodiments; and

FIG. 7 is a schematic diagram of a solar cell array according to embodiments.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of solar cells having an MXene electrode.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

The following discussion uses terms such as top, bottom, up, and down. It should be recognized that in the field of solar cells, top refers to the side of the solar cell facing the light source, bottom refers to the side of the solar cell facing away from the light source, up refers to the direction towards the light source, and down refers to the direction in which the light source travels into the solar cell.

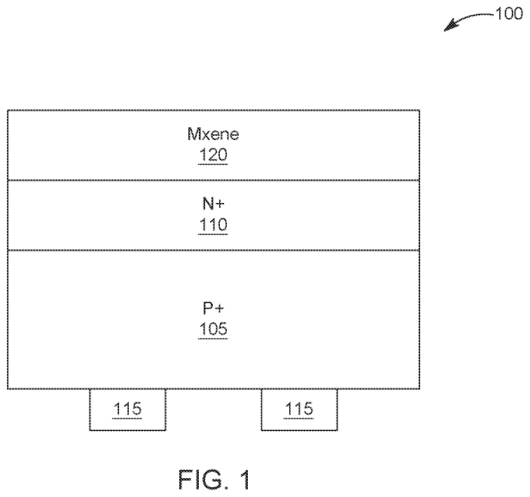

FIG. 1 is a schematic diagram of a solar cell. The solar cell 100 includes a p-type silicon layer 105 having a first side and a second side. In FIG. 1, the first side faces down and the second side faces up. The solar cell 100 also includes an n-type silicon layer 110 having a first side and a second side. In FIG. 1, the first side faces down and the second side faces up. The first side of the n-type silicon layer 110 is arranged on the second side of the p-type silicon layer 105. A first metal electrode 115 is arranged on the first side of the p-type silicon layer 105. A second metal electrode 120 is arranged on the second side of the n-type silicon layer 110. The second metal electrode 120 comprises an MXene.

In one embodiment, the MXene is an Ti₃C₂Tₓ MXene. The first metal electrode can also comprise an MXene or can comprise a transparent or non-transparent metal. Because the first metal electrode is arranged towards the bottom of the solar cell and is below the p-n junction, the first metal electrode need not been transparent because light does not need to pass through this electrode.

In the illustrated embodiment, the MXene second metal electrode 120 covers the entire top surface (i.e., the second side) of the n-type silicon layer 110. However, due to issues arising during manufacturing, the MXene second electrode 120 may cover less than the entire top surface. Nonetheless, it is advantageous to cover as much of the top surface as possible, as this maximizes the surface area of the MXene that is exposed to the incoming light, and as discussed below, the MXene electrode enhances the efficiency of the solar cell. Thus, in one embodiment the MXene second electrode 120 covers at least 90% of the top surface of the n-type silicon layer, and preferably covers the entirety of the top surface, i.e., 100% of the top surface.

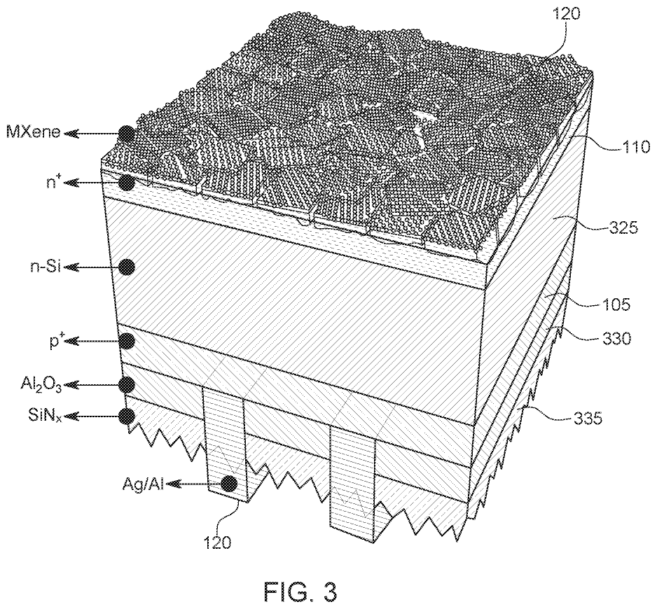

As will be described in more detail below in connection with FIG. 3, the solar cell can also include at least one passivation layer arranged adjacent to the first metal electrode. The at least one passivation layer can comprise a first passivation layer arranged directly adjacent to the first metal electrode and a second passivation layer arranged directly adjacent to the first passivation layer. The second passivation layer is a passivation and anti-reflection layer. In one embodiment, the first passivation layer comprises Al₂O₃ and the second passivation layer comprises SiNₓ. As will also be discussed in more detail below, the n-type and p-type silicon layers can be formed from a common n-type silicon layer, in which case the common n-type silicon layer is arranged between the n-type and p-type silicon layers.

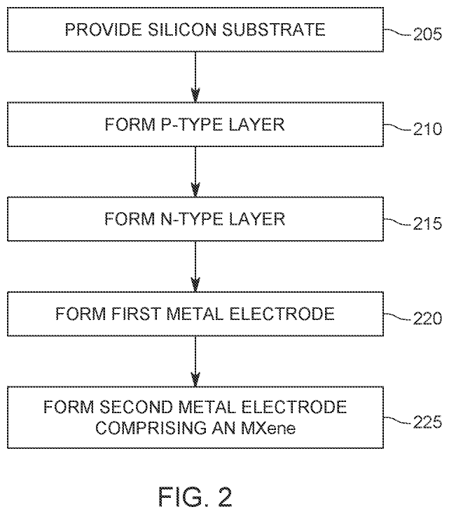

FIG. 2 is a flow diagram of a method for forming a solar cell according to embodiments. A silicon substrate is provided (step 205). A p-type layer 105 is formed on a bottom of the silicon substrate (step 210). An n-type layer 110 is formed on a top of the silicon substrate (step 215). A first metal electrode 120 is formed on a bottom of the p-type layer 105 (step 220). A second metal electrode 120, which comprises an MXene, is formed on a top of the n-type layer 110 step 225). As will be described in more detail below, the entire device, including the p-type layer 105, n-type layer 110, the first metal electrode 115, and the second metal electrode 120 can then be subjected to rapid thermal annealing, which improves the electrical contact between the second metal electrode 120 and the n-type layer 110.

In an embodiment, the p-type 105 and n-type 110 layers are formed by thermal diffusion. The second electrode 120 can be formed, for example, by drop casting. Further, a passivation layer can be formed on a bottom of the p-type layer 105 and an anti-reflective layer can be formed on a bottom of the passivation layer.

Now that an overview of the solar cell has been provided, a specific implementation will be described in connection with FIGS. 3-6.

Turning first to FIG. 3, the solar cell in this particular implementation is formed from an n-type silicon substrate 325. The p-type layer 105 is formed on the bottom side of the n-type silicon substrate 325 and the n-type layer 110 is formed on the top side of the n-type silicon substrate 325. An Al₂O₃ passivation layer 330 is formed on the bottom side of the p-type layer 105 and directly adjacent to the first metal electrode 115. An SiNₓ passivation and anti-reflective layer 335 is formed on the bottom side of the Al₂O₃ passivation layer 335. Also, the first metal contact 120 comprises gold and aluminum (Ag/Al).

Five solar cells having the structure illustrated in FIG. 3 were fabricated as follows. The Ti₃C₂Tₓ MXene was formed from the Ti₃AlC₂ MAX phase using LiF and HCl solution mixture, which selectively removed the aluminum layers from the MAX phase and thereby produced multilayer Ti₃C₂Tₓ MXene. Next, the delaminated few layered Ti₃C₂Tₓ MXene sheets were collected via a mild hand shaking process followed by several centrifugation cycles and repeated washing.

Micropyramids and microgrooves were fabricated on opposite sides of 300-μm-thick n-type (100) Si wafers 325 (containing phosphorus as a dopant with 5×10¹⁵ cm⁻³ dopant concentration), separately. On the p⁺-Si side, the textured micropyramids were fabricated by dipping as-cut silicon substrates in the anisotropic etching solution consisting of KOH, isopropyl alcohol, and H₂O for 20 min. A p⁺ emitter layer (400 nm thick) 105 was thermally diffused from the micropyramidal surface using a boron trichloride (BCl₃) source with a dopant concentration of 9×10¹⁹ cm⁻³ in a quartz tube furnace. The Al₂O₃ surface passivation layer (7 nm) 330 and a passivation and anti-reflective layer of Si₃N₄ (70 nm) 335 were then deposited on top of the emitter layer (p⁺ surface) using atomic layer deposition and plasma-enhanced chemical vapor deposition, respectively. These layers help ensure wide-range omnidirectional light-absorption and suppresses carrier recombination caused by any surface defects. Finally, an interdigitating Ag/Al electrode grid (300 nm) 120 was deposited on the p⁺-Si side of the device by inkjet-printing.

For the MXene/n⁺-Si side, the microgrooves were fabricated by immersion in a mixture of KOH, water, and isopropyl alcohol to attain the randomly distributed microgroove surface textures. The n⁺ back surface field (BSF, 70 nm thick) 110 was fabricated by the thermal diffusion of POCl₄ (dopant concentration of 3×10²⁰ cm⁻³) on the microgroove surface. This minimizes contact resistance and recombination between the MXene electrode 120 and the silicon below by keeping minority carriers (holes in this example) away from the high recombination MXene/n⁺-Si contact area. Before depositing the Ti₃C₂Tₓ MXene, the n⁺-Si side was cleaned using HF to remove the oxide layer. The prepared Ti₃C₂Tₓ MXene colloidal solution was then drop casted on the n⁺-Si side and dried in the vacuum. The Ti₃C₂Tₓ MXene uniformly covered the top surface of n⁺ layer. Furthermore, four of the solar cells were rapid thermal annealed (RTA) at different temperatures from 100 to 400° C. for 60 sec under Ar atmosphere, and one of the solar cells was not subject to rapid thermal annealing. As discussed below, the rapid thermal annealing improved the contact resistance between the MXene and the n⁺np⁺Si, which led to enhanced charge carrier transportation and decreased contact resistance.

In order to gain insight into the electronic structures of the MXene/n⁺np⁺-Si solar cells, the work function of Ti₃C₂Tₓ MXene was calculated using scanning Kelvin probe microscopy (SKPM). The thickness of drop casted Ti₃C₂Tₓ MXene nanosheets from n⁺-Si substrate was measured to be ˜12 nm, suggesting the existence of few layered MXene during the measurement. The work functions of Ti₃C₂Tₓ MXene (ϕ_{MXene}) and n⁺-Si (ϕₙ_{⁺}_{-Si}) were estimated based on the surface potential difference between Ti₃C₂Tₓ MXene and n⁺-Si using the SKPM method. The surface potential difference of 0.18 V between n⁺-Si and Ti₃C₂Tₓ MXene was obtained. Estimates of the work functions of the different layers of the solar cell are reflected in the following table:

| Φ_{MXene} | Φ_{N+-Si} | Φ_{n-Si} | Φ_{p+-Si} |
|---|---|---|---|
| 4.28 | 4.10 | 4.30 | 5.25 |

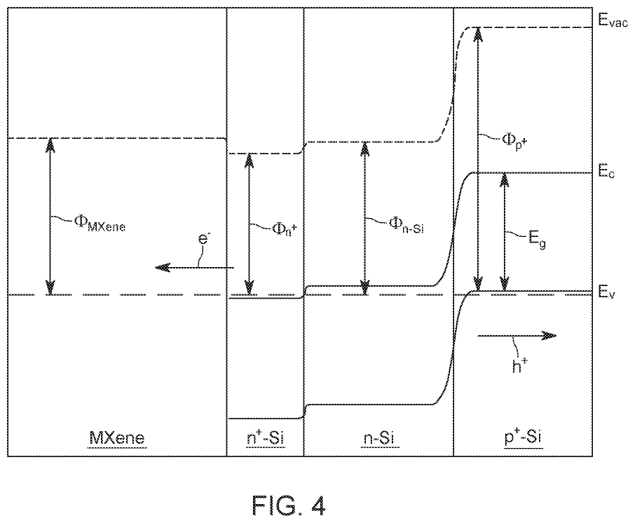

FIG. 4 is a band-diagram of the MXene/n⁺np⁺-Si solar cell based on these calculated work functions. The work function of MXene was ˜0.18 eV higher than n⁺-Si, which is sufficient to form an Ohmic contact at MXene/n⁺-Si interface. High recombination rates at the surface are known to have a particularly detrimental impact on the devices. Herein, the MXene in contact with n⁺-Si back surface field (consisting of a higher doped surface) is expected to have a major impact both on the J_{SC} and the V_{OC} by forming the superior Ohmic contact and introducing a barrier to minority carrier flow to the surface near MXene, resulting in photoexcited electrons transferred from Si to MXene electrode whereas the photogenerated holes transfer to Ag finger electrode at p⁺-Si side.

As noted above, multiple solar cells were constructed that were substantially identical, the difference being the temperature used during the rapid thermal annealing. Specifically, one of the solar cells was not subjected to rapid thermal annealing, a second was rapid thermally annealed at 100° C., a third was rapid thermally annealed at 200° C., a fourth was rapid thermally annealed at 300° C., and a fifth was rapid thermally annealed at 400° C. The photovoltaic parameters of these solar cells upon AM 1.5G illumination is reflected in the table below.

| | V_{oc} (V) | J_{sc} (mA/cm²) | FF (%) | PCE (%) |
|---|---|---|---|---|
| Before | 0.55 | 63.89 | 46.79 | 9.53 |
| Annealing | | | | |
| 100° C. | 0.55 | 38.09 | 50.21 | 10.52 |
| 200° C. | 0.54 | 37.58 | 56.05 | 11.28 |
| 300° C. | 0.54 | 36.70 | 57.99 | 11.47 |
| 400° C. | 0.53 | 37.76 | 50.79 | 10.26 |

The MXene-contacted Si solar cell before rapid thermal annealing exhibited a power conversion efficiency of 9.53% with J_{sc}=36.89 mA/cm², V_{oc}=0.55 V and FF=46.79%. The performance of the device improved gradually with as the rapid thermal annealing temperature increased up to 300° C. and then worsened when the temperature increased to 400° C. The device annealed at 300° C. exhibited the highest PCE of ˜11.5% with J_{sc}=36.70 mA/cm², V_{oc}=0.54 V and FF=57.99%. Thus, as will be appreciated, the 300° C. annealing produces a 20% enhancement in fill factor, which results in the improved power conversion efficiency.

In order to understand the effect of the rapid thermal annealing on the MXene contact to silicon, the electrical properties of Ti₃C₂Tₓ MXene films before and after rapid thermal annealing were measured using Hall measurements. The conductivity of Ti₃C₂Tₓ MXene films before and after 100, 200, 300 and 400° C. annealing was estimated to be 2.113×10³, 2.277×10³, 2.425×10³, 2.518×10³ and 0.975×10³ Ω⁻¹-cm⁻¹, respectively. The conductivity of the Ti₃C₂Tₓ MXene film increased with the increase of the rapid thermal annealing temperature up to 300° C. In contrast, the conductivity of MXene film annealed at 400° C. decreased rapidly, indicating that the Ti₃C₂Tₓ MXene film is not stable at the higher temperatures and it tends to degrade slowly.

Cell series resistance (Rₛ) for the MXene contacted Si solar cell device before and after rapid thermal annealing was calculated by extracting the slope value from the plots of dV/dln I versus I. The solar cells before and after rapid thermal annealing at 100, 200, 300 and 400° C. exhibited Rₛ values of 4.90, 4.22, 2.53, 2.38 and 2.78Ω, respectively. As will be appreciated, the solar cell subjected to the rapid thermal annealing at 300° C. exhibited low Rₛ. The observed changes in electrical conductivity and Rₛ with respect to rapid thermal annealing temperature are consistent with the changes in solar performance. Therefore, the enhancement after rapid thermal annealing can be attributed to improvement in electrical contact formation between the metallic Ti₃C₂Tₓ MXene and silicon, increased conductivity, low Rₛ and associated reduction of Ohmic losses, significantly boosting the overall power conversion efficiency of Ti₃C₂Tₓ MXene contacted silicon solar cell. Additionally, the heavily doped n⁺-Si can create an Ohmic contact with metallic Ti₃C₂Tₓ MXene and induce a built-in electric field between the silicon and the Ti₃C₂Tₓ MXene electrode to reduce the charge carrier recombination rate.

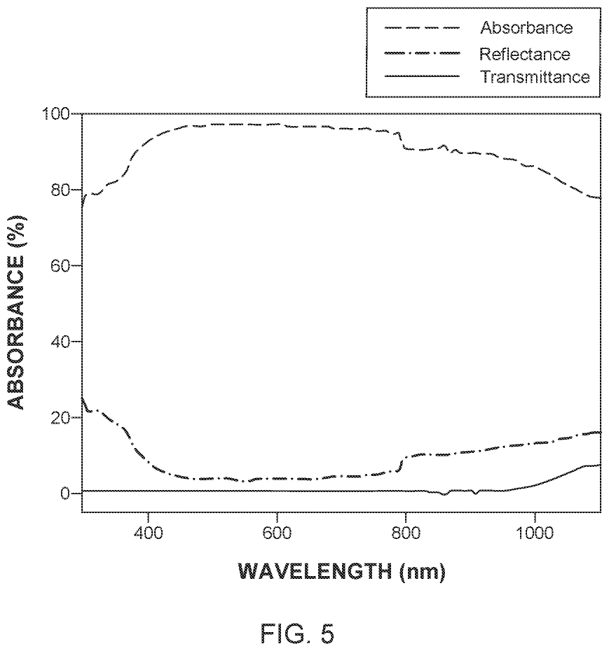

Optical characterizations were performed to gain more insight into the excellent solar cell performance of MXene contacted silicon cells. As illustrated in FIG. 5, n⁺np⁺-Si has low reflection and high absorption in the wavelength region of 400 to 1000 nm of the solar spectrum due to the pyramidal surfaces with SiNₓ anti-reflective coating efficiently capturing the light and groove internal reflector surfaces with MXene contact allowing light to randomly bounce back into the silicon to improve absorption. It is known that the photo-excited charge carriers can easily be recombined on the surface defect sites that further leads to poor carrier collection efficiency. Rapid thermal annealing was demonstrated to improve the contact parameters and reduce the leakage current and series resistivity.

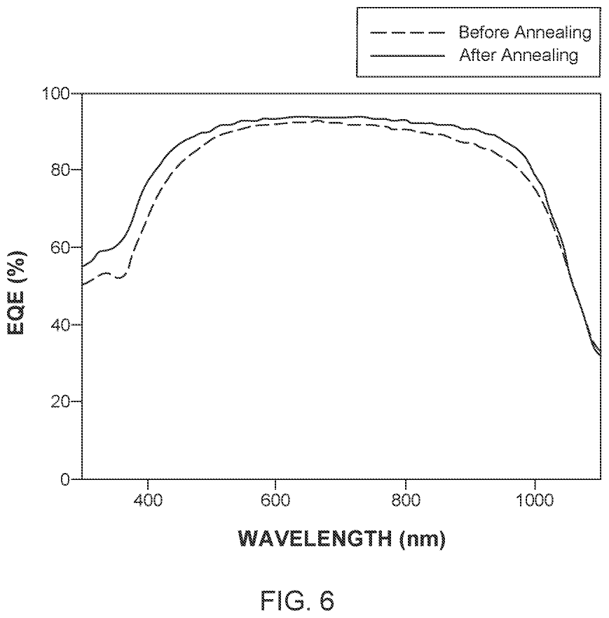

The external quantum efficiency (EQE) characterization for evaluating the photogenerated carrier generation and charge carrier collection efficiency of the solar cell was measured with Ti₃C₂Tₓ MXene contacted silicon cells before and after rapid thermal annealing, the results of which are illustrated in FIG. 6. The 300° C. annealed Ti₃C₂Tₓ MXene/n⁺np⁺-Si exhibited an external quantum efficiency of more than 90%, in the wavelength range from 450 to 900 nm, which indicated that Ti₃C₂Tₓ MXene can be used as a metal contact that effectively extracts photogenerated electrons from the silicon solar cell and thereby improves the external quantum efficiency in the wide wavelength range.

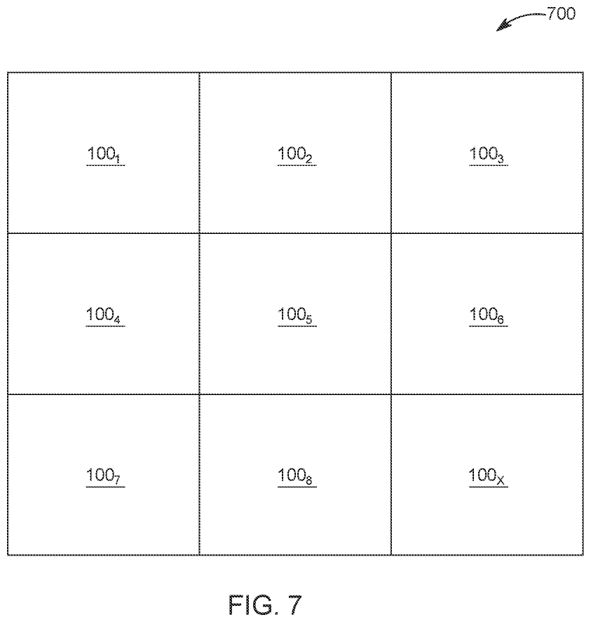

Finally, the disclosed solar cell can be used as part of a solar cell array, an example of which is illustrated in FIG. 7. Specifically, the solar cell array 700 includes a plurality of solar cells 100₁-100ₓ. Each of these solar cells includes a p-type silicon layer 105 having a first side and a second side, an n-type silicon layer 110 having a first side and a second side with the first side of the n-type silicon layer 110 being arranged on the second side of the p-type silicon layer 105, a first metal electrode 115 arranged on the first side of the p-type silicon layer 105, a second metal electrode 120 arranged on the second side of the n-type silicon layer 110. The second metal electrode 120 comprises an MXene.

As will be appreciated from the discussion above, the delaminated few layered Ti₃C₂Tₓ MXene-contacted Si solar cell exhibited a maximum power conversion efficiency of ˜11.5%, which is significantly higher than has been achieved with other types of two-dimensional materials. The Ohmic contact formation between metallic Ti₃C₂Tₓ MXene and a heavily doped silicon surface decreased contact resistance and suppressed charge carrier recombination, which resulted in excellent V_{oc} and J_{sc}. The rapid thermal annealing process improved electrical conductivity, reduced sheet resistance of Ti₃C₂Tₓ MXene nanosheet films, and the cell series resistance of Ti₃C₂Tₓ MXene-contacted Si solar cells, leading to improved fill factor and overall power conversion efficiency. Thus, the discussion above demonstrates that solution processable MXene is a potential contact material for optoelectronic devices.

The disclosed embodiments provide a solar cell with an MXene electrode, a solar cell array comprising these solar cells, and methods of production. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A solar cell, comprising:
a p-type silicon layer having a first side and a second side;
an n-type silicon layer having a first side and a second side, wherein the first side of the n-type silicon layer is arranged on the second side of the p-type silicon layer;
a first metal electrode arranged on the first side of the p-type silicon layer; and
a second metal electrode arranged on the second side of the n-type silicon layer, wherein the second metal electrode comprises an MXene.

2. The solar cell of claim 1, wherein the MXene is a Ti₃C₂Tₓ MXene.

3. The solar cell of claim 1, wherein the first metal electrode comprises an MXene.

4. The solar cell of claim 1, wherein the first metal electrode comprises a non-transparent metal.

5. The solar cell of claim 1, wherein the second metal electrode covers at least 90% of the second side of the n-type silicon layer.

6. The solar cell of claim 1, further comprising:
at least one passivation layer arranged adjacent to the first metal electrode.

7. The solar cell of claim 6, wherein the at least one passivation layer comprises:
a first passivation layer arranged directly adjacent to the first metal electrode; and
a second passivation layer arranged directly adjacent to the first passivation layer, wherein the second passivation layer is a passivation and anti-reflection layer.

8. The solar cell of claim 7, wherein the first passivation layer comprises Al₂O₃ and the second passivation layer comprises SiNₓ.

9. The solar cell of claim 1, further comprising:
a second n-type silicon layer arranged between the n-type and p-type silicon layers.

10. A method for forming a solar cell, the method comprising:
providing a silicon substrate;
forming a p-type layer on a bottom of the silicon substrate;
forming an n-type layer on a top of the silicon substrate;
forming a first metal electrode on a bottom of the p-type layer; and
forming a second metal electrode on a top of the n-type layer, wherein the second metal electrode comprises an MXene.

11. The method of claim 10, wherein the p-type and n-type layers are formed by thermal diffusion.

12. The method of claim 10, wherein the second metal electrode is formed on the top of the n-type layer by drop casting.

13. The method of claim 10, further comprising:
rapid thermal annealing the solar cell including the silicon substrate, p-type layer, n-type layer, the first metal electrode, and the second metal electrode.

14. The method of claim 10, further comprising:
forming a passivation layer on a bottom of the p-type layer.

15. The method of claim 14, further comprising:
forming an anti-reflective layer on a bottom of the passivation layer.

16. A solar cell array, comprising:
a plurality of solar cells, each of the plurality of solar cells comprising
a p-type silicon layer having a first side and a second side;
an n-type silicon layer having a first side and a second side, wherein the first side of the n-type silicon layer is arranged on the second side of the p-type silicon layer;
a first metal electrode arranged on the first side of the p-type silicon layer; and
a second metal electrode arranged on the second side of the n-type silicon layer, wherein the second metal electrode comprises an MXene.

17. The solar cell array of claim 16, wherein the MXene is a Ti₃C₂Tₓ MXene.

18. The solar cell array of claim 16, wherein the first metal electrode comprises an MXene.

19. The solar cell array of claim 16, wherein the first metal electrode comprises a non-transparent metal.

20. The solar cell array of claim 16, wherein the second metal electrode covers at least 90% of the second side of the n-type silicon layer.
